(19) United States
(12) Patent Application Publication
(10) Pub. No.: US 2024/0015954 A1
(43) Pub. Date: Jan. 11, 2024

(54) MEMORY AND MANUFACTURING METHOD THEREOF

(71) Applicant: CHANGXIN MEMORY TECHNOLOGIES, INC., Hefei City (CN)

(72) Inventor: CHIH-CHENG LIU, Hefei City (CN)

(73) Assignee: CHANGXIN MEMORY TECHNOLOGIES, INC., Hefei City (CN)

(21) Appl. No.: 18/448,942

(22) Filed: Aug. 13, 2023

Related U.S. Application Data
(63) Continuation of application No. PCT/CN2022/070840, filed on Jan. 7, 2022.

(30) Foreign Application Priority Data
Oct. 15, 2021 (CN) 202111205695.3

(51) Int. Cl. H10B 12/00

(52) U.S. Cl. CPC H10B 12/482; H10B 12/488; H10B 12/03

(57) ABSTRACT

A memory includes a substrate; a plurality of bit lines on the substrate, which are parallel to each other and extend in a first direction; a plurality of active pillars on the bit lines, bottom ends of which are connected to the bit lines; a plurality of word lines parallel to each other and extending in a second direction, which surround outer sidewalls of the active pillars, and expose top ends of the active pillars, the active pillars and the word lines jointly constitute vertical memory transistors of the memory; and a plurality of capacitors and a plurality of connecting pads, each of the capacitors is located on each of the active pillars, each of the connecting pads is located between the active pillar and the capacitor.

### CROSS-REFERENCE TO RELATED APPLICATIONS

This is a continuation of International Patent Application No. PCT/CN2022/070840 field on Jan. 7, 2022, which claims priority to Chinese Patent Application No. 202111205695.3 filed on Oct. 15, 2021. The disclosures of the above-referenced applications are hereby incorporated by reference in their entirety.

### BACKGROUND

With the continuous improvement of computing speed, computing capacity and other requirements, the requirement of the application side for the storage density of the memory is increasingly higher. In order to meet the increasing storage density requirement of the application side, seeking a memory that is beneficial to integration is a subject that those skilled in related art need to solve.

### SUMMARY

The disclosure relates to the field of semiconductor technology, in particular to a memory and a method for manufacturing the same.

In view of this, embodiments of the disclosure provide a memory and a method for manufacturing the same.

According to the first aspect of the embodiments of the disclosure, a memory is provided. The memory includes a substrate, a plurality of bit lines, a plurality of active pillars, a plurality of word lines, and a plurality of capacitors and a plurality of connecting pads.

The plurality of bit lines are located on the substrate. The plurality of bit lines are parallel to each other and extend in a first direction.

The plurality of active pillars are located on the bit lines. Bottom ends of the active pillars are connected to the bit lines.

The plurality of word lines are parallel to each other and extend in a second direction. The word lines surround outer sidewalls of the active pillars and expose top ends of the active pillars. The active pillars and the word lines jointly constitute vertical memory transistors of the memory.

Each of the capacitors is located on each of the active pillars. Each of the connecting pads is located between the active pillar and the capacitor for electrically connecting the active pillar and the capacitor.

The first direction and the second direction are perpendicular to each other. The plurality of active pillars are arranged in hexagonal array.

According to the second aspect of the embodiments of the disclosure, a method for manufacturing a memory is provided. The method includes the following operations.

A substrate is provided.

A plurality of active pillars are formed. The plurality of active pillars are disposed on the substrate and arranged in hexagonal array.

A plurality of bit lines are formed. The bit lines are parallel to each other and extend in a first direction, and bottom ends of the active pillars are connected to the bit lines.

Connecting pads are formed. Each of the connecting pads is disposed at a top of each of the active pillars and electrically connected with the active pillars.

A plurality of word lines are formed. The word lines are parallel to each other and extend in a second direction perpendicular to the first direction. The word lines surround outer sidewalls of the active pillars and expose top ends of the active pillars and the connecting pads. The active pillars and the word lines jointly constitute vertical memory transistors of the memory.

A plurality of capacitors are formed. Each of the capacitors is disposed on and electrically connected with each of the connecting pads.

Parts of additional aspects and advantages of the disclosure will be set forth in the following description, and the part will become apparent from the following description or will become apparent through the practice of the disclosure.

### BRIEF DESCRIPTION OF THE DRAWINGS

FIG. 1A is a schematic top view of a memory in an embodiment of the disclosure.

FIG. 1B is a schematic top view of a structure of the memory after stripping capacitors and word lines in the embodiment of the disclosure.

FIG. 1C is a schematic cross-sectional view of the memory along line AA′ in FIG. 1A in the embodiment of the disclosure.

FIG. 1D is a schematic top view of a structure of word lines in another embodiment.

FIG. 1E is a schematic top view of active pillars and bit lines in an embodiment of the disclosure.

FIG. 1F is a schematic cross-sectional view of a memory along line BB′ in FIG. 1E in the embodiment of the disclosure.

FIG. 1G is a schematic cross-sectional view of a memory along line CC′ in FIG. 1E in the embodiment of the disclosure.

FIG. 1H is a schematic top view of contact layers.

FIG. 2 is a flowchart showing a method for manufacturing a memory in an embodiment of the disclosure.

FIG. 3A shows first schematic diagrams of device structures in a process for manufacturing a memory provided by an embodiment of the disclosure, in which sub-FIG. 1 is a schematic cross-sectional view and sub-FIG. 1I is a schematic top view.

FIG. 3B shows second schematic diagrams of device structures in a process for manufacturing a memory provided by an embodiment of the disclosure, in which sub-FIG. 1 is a schematic cross-sectional view and sub-FIG. 1I is a schematic top view.

FIG. 3C shows third schematic diagrams of device structures in a process for manufacturing a memory provided by an embodiment of the disclosure, in which sub-FIG. 1 is a schematic cross-sectional view and sub-FIG. 1I is a schematic top view.

FIG. 3D shows a fourth schematic diagram of device structures in a process for manufacturing a memory provided by an embodiment of the disclosure.

FIG. 3E shows a fifth schematic diagram of device structures in a process for manufacturing a memory provided by an embodiment of the disclosure.

FIG. 3F shows sixth schematic diagrams of device structures in a process for manufacturing a memory provided by an embodiment of the disclosure, in which sub-FIG. 1 is a schematic cross-sectional view and sub-FIG. 1I is a schematic top view.

FIG. 3G shows seventh schematic diagrams of device structures in a process for manufacturing a memory provided by an embodiment of the disclosure, in which sub-FIG. 1 is a schematic cross-sectional view and sub-FIG. 1I is a schematic top view.

FIG. 3H shows eighth schematic diagrams of device structures in a process for manufacturing a memory provided by an embodiment of the disclosure, in which sub-FIG. 1 is a schematic cross-sectional view and sub-FIG. 1I is a schematic top view.

### DETAILED DESCRIPTION

Exemplary embodiments of the disclosure will be described in more detail below with reference to the accompanying drawings. Although the exemplary embodiments of the disclosure are shown in the accompanying drawings, it is to be understood that the disclosure may be implemented in various forms and should not be limited to the specific embodiments set forth herein. These embodiments are provided for the purpose that the disclosure will be more thorough understood and the scope of the disclosure will be fully conveyed to those skilled in the art.

In the drawings, the dimensions of layers, regions, elements and their relative dimensions may be exaggerated for clarity. The same reference numeral denotes the same elements throughout the text.

It should be understood that when an element or a layer is referred to as “on”, “adjacent to”, “connected to”, or “coupled to” another element or layer, it may be directly on the other element or layer, adjacent to the other element or layer, or connected to or coupled to the other element or layer, or there may be an intermediate element or layer therebetween. On the contrary, when an element is described as “directly on”, “directly adjacent to”, “directly connected to” or “directly coupled to” another element or layer, there is no intermediate element or layer therebetween. It should be understood that although the terms “first”, “second”, “third”, and the like may be used to describe various elements, components, regions, layers and/or parts, these elements, components, regions, layers and/or parts should not be limited by these terms. These terms are only used to distinguish one element, component, region, layer or part from another element, component, region, layer or part. Therefore, without departing from the teaching of the disclosure, a first element, component, region, layer or part discussed hereinafter may be expressed as a second element, component, region, layer or part. While discussing a second element, component, region, layer or part, it does not imply that a first element, component, region, layer or part is necessarily present in the disclosure.

Spatial relationship terms such as “below”, “under”, “lower”, “beneath”, “above”, and “upper” may be used herein for convenience to describe a relationship between one element or feature and another element or feature illustrated in the figures. It should be understood that, the spatial relationship terms tend to further include different orientations of devices in use and operation in addition to the orientation shown in the drawings. For example, if the device in the drawings is turned over, an element or feature described as being “under” or “beneath” or “below” another elements or features will be oriented to be “on” the other elements or features. Therefore, the exemplary terms “under” and “below” may include both up and down orientations. The device may also include additional orientations (e.g. rotation for 90 degrees or other orientations) and the spatial terms used herein are interpreted accordingly.

The terms used herein are intended to describe specific embodiments only and are not to be a limitation of the disclosure. As used herein, the singular forms of “a/an”, “one” and “said/the” are also intended to include the plural forms, unless the context clearly indicates otherwise. It should be further understood that the terms “consist of” and/or “comprise/include” used in the specification mean that the stated features, integers, steps, operations, elements and/or components are present, but the presence or addition of one or more other features, integers, steps, operations, elements, components and/or combinations is not excluded. As used herein, the term “and/or” includes any of the listed items and all combinations thereof.

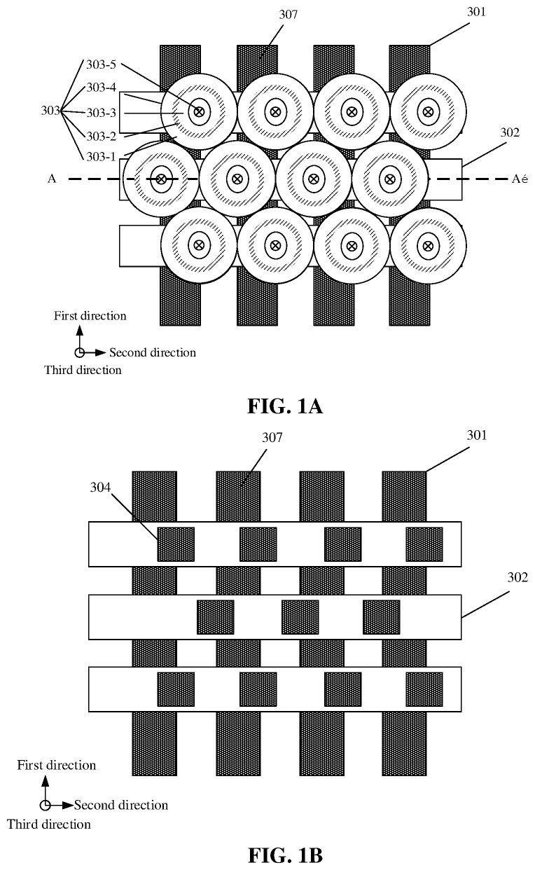

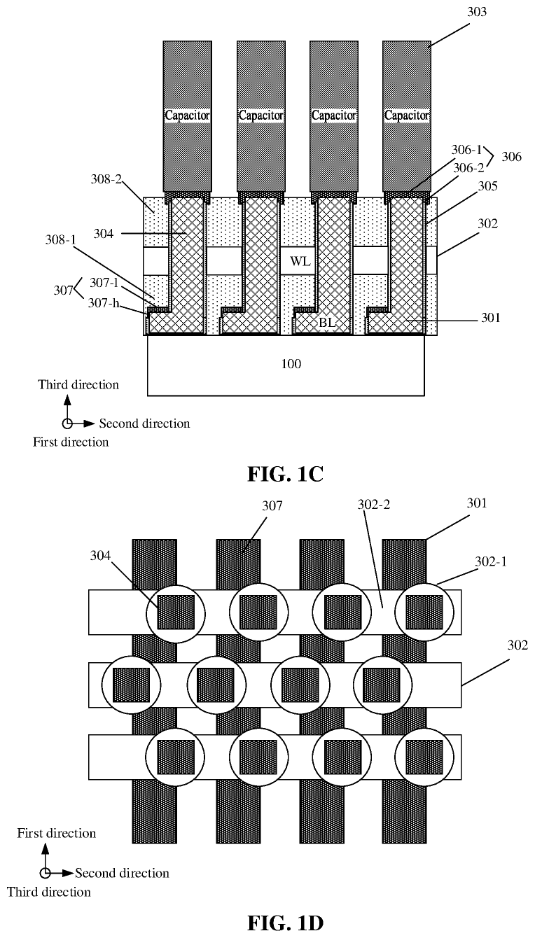

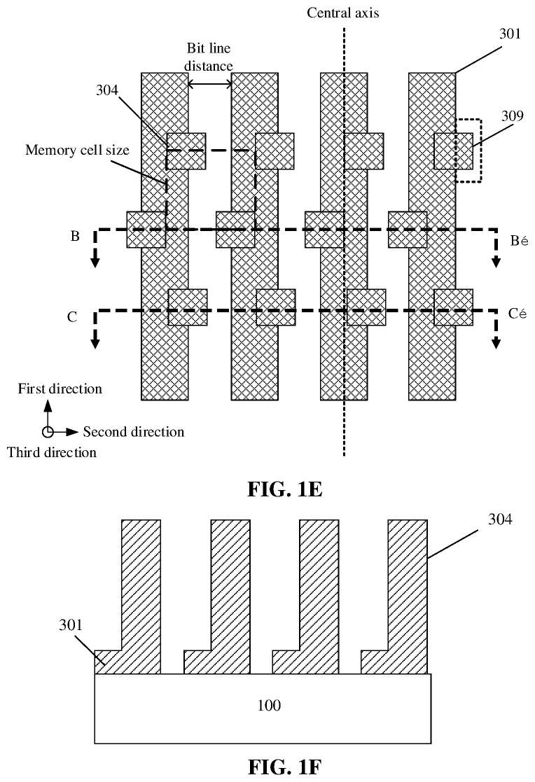

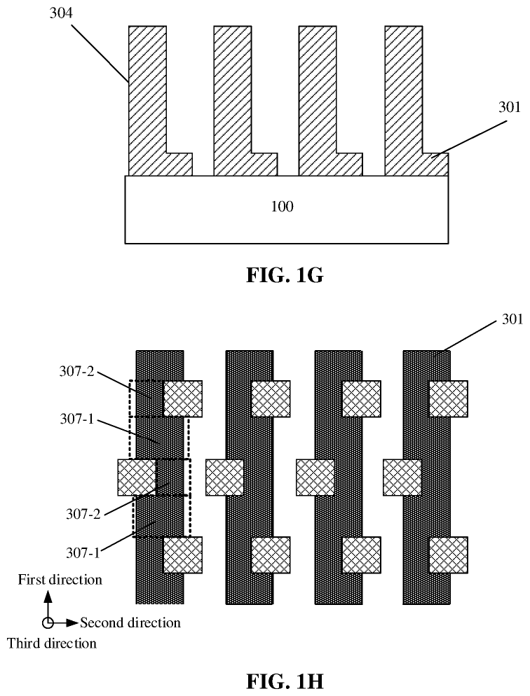

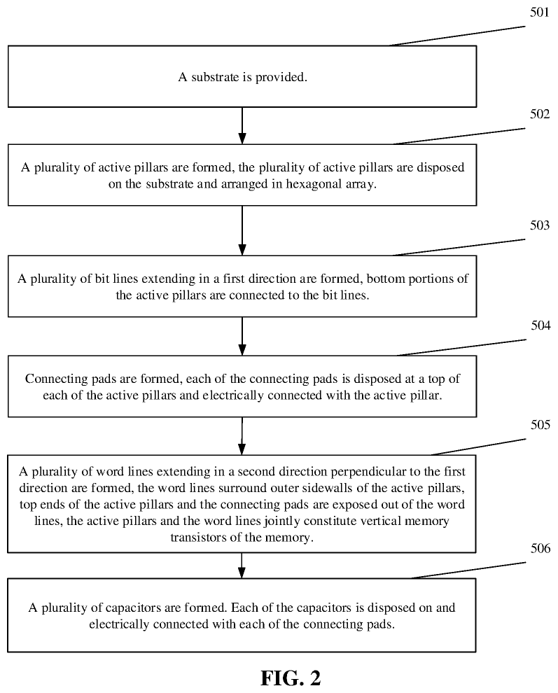

The disclosure provides a memory. FIG. 1A is a top view of a memory in the disclosure FIG. 1B is a top view of the memory after stripping capacitors. FIG. 1C is a vertical cross-sectional view of the memory along line AA′ in FIG. 1A. In combination with FIG. 1A to FIG. 1C, the memory includes a substrate 100, a plurality of bit lines 301, a plurality of active pillars 304, a plurality of word lines 302, and a plurality of capacitors 303 and a plurality of connecting pads 306.

The plurality of bit lines 301 are located on the substrate 100. The plurality of bit lines 301 are parallel to each other and extend in a first direction.

The plurality of active pillars 304 are located on the bit lines 301, and bottom ends of the active pillars 304 are connected to the bit lines 301.

The plurality of word lines 302 are parallel to each other and extend in a second direction. The word lines 302 surround outer sidewalls of the active pillars 304, and expose top ends of the active pillars 304 (referring to FIG. 1B). The active pillars 304 and the word lines 302 jointly constitute vertical memory transistors of the memory.

Each of the capacitors 303 is located on each of the active pillars 304. Each of the connecting pads 306 is located between the active pillar 304 and the capacitor 303 for electrically connecting the active pillar 304 and the capacitor 303.

The first direction and the second direction are perpendicular to each other. The plurality of active pillars 304 are arranged in a hexagonal array manner.

In practice, the substrate 100 may be, for example, a substrate of an elemental semiconductor material (for example, silicon (Si) substrate, germanium (Ge) substrate, etc.), a substrate of a composite semiconductor material (for example, silicon germanium (SiGe) substrate, etc.), or a silicon on insulator (SOI) substrate, a germanium on insulator (GeOI) substrate, or the like. In a specific embodiment, the substrate 100 is a silicon-on-insulator (SOI) substrate. Vertical transistors are disposed on the SOI substrate, such that the capacitance of the bit lines can be reduced, and further a ratio of Cs/Cbl can be increased to improve an access domain, in which Cs refers to the capacitance of a single capacitor cell and Cbl is the capacitance of the whole bit lines.

In an embodiment, the bit lines 301 and the active pillars 304 may include a same material, such as a semiconductor material, including but not limited to silicon (Si), silicon germanium (SiGe), zinc oxide (ZnO), or Group III-V semiconductor materials, etc. In some embodiments, the bit lines 301 may include heavy doped regions, regions of the active pillars 304 surrounded and covered by the word lines 302 include channel doped regions, upper regions and lower regions of the active pillars 304 not surrounded and covered by the word lines 302 include source/drain doped regions. The upper portions and lower portions may serve as source/drains or drain/sources of the vertical transistors, respectively. A doping type of the channel doped regions is opposite to a doping type of the source-drain doped regions. In practice, the bit lines 301 and the active pillars 304 may be formed in a same semiconductor material by etching, to realize the connection of the bottom ends of the active pillars 304 with the bit lines 301. In other embodiments, the bit lines 301 and the active pillars 304 may include different materials. For example, the bit lines 301 and the active pillars 304 may include different semiconductor materials, or the bit lines 301 include a metal material and the active pillars 304 include a semiconductor material. In some embodiments, a connecting piece may also be include between each of the bit lines 301 and each of the active pillars 304, through which the bit line 301 and the active pillar 304 are electrically connected, thereby reducing the contact resistance between the bit line 301 and the active pillar 304.

In practice, a material of the word lines 302 may include a conductive material. The conductive material includes, but is not limited to tungsten (W), cobalt (Co), copper (Cu), aluminum (Al), polysilicon, a doped silicon, a silicide, or any combination thereof.

A material of the connecting pads 306 may include, but is not limited to a metal silicide, specifically such as tungsten silicide, cobalt silicide, and the like. According to the embodiment of the disclosure, a metal silicide material is selected for serving as the material of the connecting pads, since the characteristics of resistance and the high melting point of the metal silicide, RC resistance can be reduced, and meanwhile adapting to a process for forming capacitor at high temperature can be allowed.

In some other embodiments, each of the connecting pads 306 may include a multi-layer structure, and materials of respective layers of the multi-layer structure are different. The arrangement of the multi-layer structure allows the resistance and the melting point of the metal silicide material to be flexibly adjusted, so as to obtain a best device performance and a good process.

In an embodiment, as shown in FIG. 1A, each of the capacitors 303 may include an inner capacitor protective layer 303-5, an capacitor upper electrode 303-4, a capacitor dielectric layer 303-3, a capacitor lower electrode 303-2, and an outer capacitor protective layer 303-1 from inside to outside. Here, the plurality of capacitors 303 are disposed in a hexagonal closet pack. The “hexagonal closet pack” described herein refers to a closest hexagonal distribution that the capacitors 303 can achieve under a minimum limit of line width dimension and a minimum limit of line spacing dimension that may be obtained based on a resolution of the current lithography equipment.

In an embodiment, as shown in FIG. 1C, the memory also includes gate insulating layers 305. The gate insulating layers 305 cover the sidewalls of the active pillars 304, for isolating the active pillars 304 from the word lines 302. Portions of the word lines 302 surrounding the active pillars 304 constitute gates of the vertical transistors. The turn-on and turn-off of the vertical transistors can be controlled by control the voltage applied by the word lines 302. In some embodiments, the gate insulating layers 305 also cover sidewalls of the bit lines 301 for isolating the bit lines 301, so as to avoid short circuit of the bit lines and other influences on device stability.

In an embodiment, as shown in FIG. 1C, the memory provided by the disclosure further includes a lower filling layer 308-1 and an upper filling layer 308-2. The lower filling layer 308-1 and the upper filling layer 308-2 cover portions of the active pillars 304 not covered by the word lines 302 and wrap the word lines 302. The materials of the lower filling layer 308-1 and the upper filling layer 308-2 include, but are not limited to, silicon oxide, silicon nitride, silicon oxynitride or a polymer material and the like. In some embodiments, the upper filling layer and the lower filling layer may be made of different materials.

In a specific embodiment, as shown in FIG. 1C, each of the connecting pads 306 may include a first connecting pad 306-1 extending perpendicular to the third direction and a second connecting pad 306-2 extending parallel to the third direction. The first connecting pad 306-1 covers the top of one of the active pillars 304. The second connecting pad 306-2 is in contact with the first connecting pad and covers a part of along the sidewalls of the one of the active pillars 304 and may be in contact with the sidewalls of the active pillar 304. The third direction is perpendicular to the first direction and the second direction. By disposing the second connecting pad 306-2 extending along the sidewalls of the active pillar 304, on the one hand, the contact area between the connecting pad 306 and the active pillar 304 is increased, which makes the active pillar better wrapped; moreover, the contact area between the connecting pad and the active pillar is increased, which can prevent the capacitor from being in contact with the gate insulating layer and affecting the electrical performance when the capacitor is formed subsequently, and can better form an isolation structure with a neighboring filling layer. On the other hand, when the connecting pad is only disposed on the top of the active pillar 304, a current flows from the connecting pad to the channel region in the middle of the active pillar through the top of the active pillar; while when the second connecting pad 306-2 extends downward along the sidewall, the current may be directly transmitted to the channel region through the sidewall portion of the second connecting pad 306-2, which shortens the path of the current, reduces a resistance, thereby improves the device performance.

In some embodiments, a ratio of the height of the second connecting pad 306-2 along the third direction to a height of a portion of the active pillars 304 above the word lines along the third direction is 0.5-0.75, such as 0.55, 0.6 and 0.68. Two adjacent ones of the second connecting pads 306-2 and a dielectric layer or a semiconductor layer between the two adjacent second connecting pads 306-2 may form a large parasitic capacitance, which is unfavorable to the device performance. When the ratio is greater than 0.75, the above-mentioned parasitic capacitance is larger, which has a greater influence on the device performance. When the ratio is less than 0.5, it will be difficult to obtain the optimal effect of reducing the resistance.

In some embodiments, the second connecting pad 306-2 may be disposed only on one side of the active pillar 304. The second connecting pad is only disposed on one side of the active pillar, while the second connecting pad on the other side is absent, such that a formation of the parasitic capacitor can be reduced, which is beneficial to the electrical performance of the device.

In the embodiment shown in FIG. 1A to FIG. 1C, each of the word lines 302 is formed as a whole, and the region of the word line 302 surrounding the active pillars 304 form gates. In some other embodiments, as shown in FIG. 1D, each of the word lines 302 may also be composed of two parts. One part is a plurality of tubular gates 302-1 surrounding the active pillars 304, and the other part is a plurality of word line connecting portions 302-2 which connect the adjacent tubular gates. The plurality of tubular gates and the plurality of word line connecting portions are alternately connected and arranged along the second direction. In the embodiment, the tubular gates and the word-line connecting portions may be made of different materials. In some embodiments, the material of the tubular gates may, for example, include a laminated structure, such as a gate work function layer and a gate conductive layer sequentially stacked. The material of the gate work function layer includes, for example, one of titanium (Ti) and titanium nitride (TiN), or a combination thereof. The material of the gate conductive layer includes, for example, one of polysilicon (Poly) and tungsten (W), or a combination thereof.

In some embodiments, as shown in FIG. 1E, a projection on a plane perpendicular to a third direction, a center of each of the active pillars 304 is offset from a central axis of the bit line 301 to which the active pillar is connected along a third direction, and the centers of two adjacent ones of the active pillars on a same bit line are offset in opposite directions from the central axis of the bit line. The third direction is perpendicular to the first direction and the second direction, and the central axis of the bit line 301 is a central axis of the bit line 301 extending along the first direction.

FIG. 1F and FIG. 1G are vertical schematic cross-sectional views along dashed lines BB′ and CC′ in FIG. 1E. As shown in FIG. 1F to FIG. 1G, in some embodiments, the centers of two adjacent ones of the active pillars 304 disposed on a same bit line 301 are offset in opposite directions to the central axis of the bit line 301. The hexagonal closet pack of the capacitors can be implemented by means of alternatively offsetting of the active pillars in the above-mentioned solution.

In an embodiment, one of the vertical memory transistors and the capacitor 303 located on the vertical memory transistor constitute a memory cell, and a cell size of the memory cell is 4F². For example, the memory cells may include two lithographic features (2F) on a vertical axis crossed with two lithographic features on a horizontal axis to produce the memory cell within four lithographic features squared (4F²). Here, the cell size is a size of an occupied area of the memory cell on the substrate 100. Specifically, as shown in FIG. 1E, an occupied area of one of the vertical transistors on the substrate 100 is a square with a side length F. Since the memory cell is composed of a vertical transistor and a capacitor 303 formed on the vertical transistor, the occupied area of the capacitor, the occupied area of the memory cell are equal to the occupied area of the vertical transistor, and are all the areas of the square with the side length F. Herein, “F” is a minimum limit linewidth dimension and a minimum limit linespacing dimension that may be obtained based on a resolution of a lithography equipment. Under the cell size, the capacitors will be in the closest hexagonal closet pack, which means that the memory can obtain a maximum storage density.

In an embodiment, as shown in FIG. 1E, the plurality of bit lines 301 are arranged in parallel and spaced apart from each other at an equal interval. A distance between two adjacent ones of the bit lines 301 is the bit line distance D, and a distance between the center of each of the active pillars 304 and the central axis of the corresponding bit line to which the active pillar is connected is the offset distance d, in which a ratio of the offset distance d to the bit line distance D is ⅓ to ⅔, such as ⅓ or ½. When the ratio is greater than ⅔, a width of the protrusions 309 is excessive, which causes a distance between the protrusions 309 and the adjacent bit line 301 to be too close, thus causing device stability problems such as unnecessary short connection between the protrusions and the adjacent bit lines, and further increasing the difficulty of etching and manufacturing the bit lines and the active pillars. In addition, when the ratio is less than ⅓, the width of the protrusions is too small, the area covered by the active pillars of the bit line increases, such that the space reserved for contact layers decreases, and the resistance of the bit lines increases, thus affecting the device performance. In the embodiments of the disclosure, the ratio of d to D is selected in the above range, so that the optimal resistance of the bit lines and the optimal device stability can be obtained. In some embodiments, the offset distance d may be ½ of the bit line distance D.

In some embodiments, as shown in FIG. 1C, the memory provided by the disclosure also includes contact layers 307. Each of the contact layers 307 is disposed on and electrically connected with a corresponding one of the bit lines 301. In an embodiment, the contact layers 307 extend in the first direction and are wavy. For example, FIG. 1H is a schematic top view of the contact layers. As shown in FIG. 1H, each of the contact layers 307 includes first contact portions 307-1 and second contact portions 307-2 alternately connected along the first direction (as shown in a dashed box). The width of the first contact portions 307-1 along the second direction is greater than the width of the second contact portions 307-2 along the second direction; the width of the first contact portions 307-1 along the second direction is equal to the width of the bit lines; the width of the second contact portions 307-2 along the second direction is smaller than the width of the bit lines 301; and the central axes of two adjacent ones of the second contact portions 307-2 along the first direction do not coincide. In an embodiment, the sidewalls of the contact layers 307 may also be in contact with the sidewalls of the active pillars 304.

In practice, the material of the contact layers 307 includes, but is not limited to a metal silicide, specifically, such as tungsten silicide, cobalt silicide, etc. The metal silicide material with a high melting point can reduce the resistance of the bit lines, and meanwhile can allow sustaining a high temperature capacitor process. In the embodiment where the sidewalls of each of the contact layers 307 are in contact with the sidewalls of the active pillars 304, the contact layers 307 are in contact with the active pillars 304, which can further reduce the contact resistance between the bit lines 301 and the active pillars 304.

In some embodiments, the materials of the contact layers 307 and the connecting pads 306 may be the same, which allows the contact layers 307 and the connecting pads 306 to be simultaneously formed at the same time, thereby simplifying the operations and saving the process.

In some specific embodiments, as shown in FIG. 1C, each of the contact layers 307 further include a horizontal portion 307-1 extending perpendicular to the third direction and a vertical portion 307-h extending parallel to the third direction. The third direction is perpendicular to the first direction and the second direction. The horizontal portion 307-1 covers the top of each of the bit lines and the vertical portion 307-h extends along the sidewalls of the bit line. By disposing the vertical portion 307-h extending along the sidewalls of each of the bit lines 301, the contact area between the contact layer 307 and the bit line 301 is increased, such that the RC resistance is reduced, and the performance of the contact layer 307 wrapping the bit line 301 is increased.

In some embodiments, a ratio of the height of the vertical portions along the third direction to the height of the bit lines along the third direction is 0.6-0.9, such as and 0.85. When the ratio is greater than 0.9, a large parasitic capacitor may be formed between two adjacent ones of the vertical portions and a dielectric layer and a semiconductor layer between the two adjacent vertical portions, which is unfavorable to the device performance. When the ratio is less than 0.6, it will be difficult to obtain an optimal effect of reducing the contact resistance.

In some other embodiments, each of the contact layers 307 may include a multi-layer structure, and the materials of respective layers of the multi-layer structure may be different. By disposing the multi-layer structure, a resistance and a melting point of the contact layers can be flexibly adjusted to obtain a best device performance and a good process.

According to the embodiments of the disclosure, a method for manufacturing a memory is provided. Specifically, refereeing to FIG. 2, and as shown in the figure, the method includes the following operations.

In an operation 501, a substrate is provided.

In an operation 502, a plurality of active pillars are formed, the plurality of active pillars are disposed on the substrate and arranged in hexagonal array.

In an operation 503, a plurality of bit lines are formed. The bit lines are parallel to each other and extend in a first direction. Bottom ends of the active pillars are connected to the bit lines.

In an operation 504, connecting pads are formed. Each of the connecting pads is disposed at a top of each of the active pillars and electrically connected with the active pillar.

In an operation 505, a plurality of word lines extending in a second direction perpendicular to the first direction are formed. The word lines surround outer sidewalls of the active pillars, and expose top ends of the active pillars and the connecting pads. The active pillars and the word lines jointly constitute vertical memory transistors of the memory.

In an operation 506, a plurality of capacitors are formed. Each of the capacitors is disposed on and electrically connected with each of the connecting pads.

The method for manufacturing a memory provided by the embodiments of the disclosure will be described in further detail below in combination with the specific embodiments.

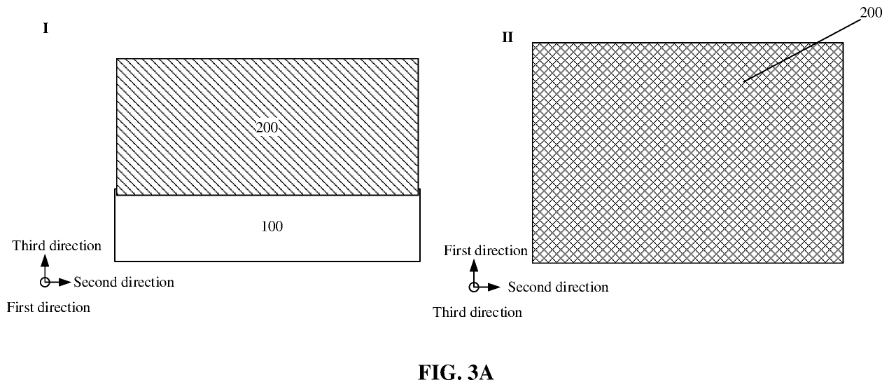

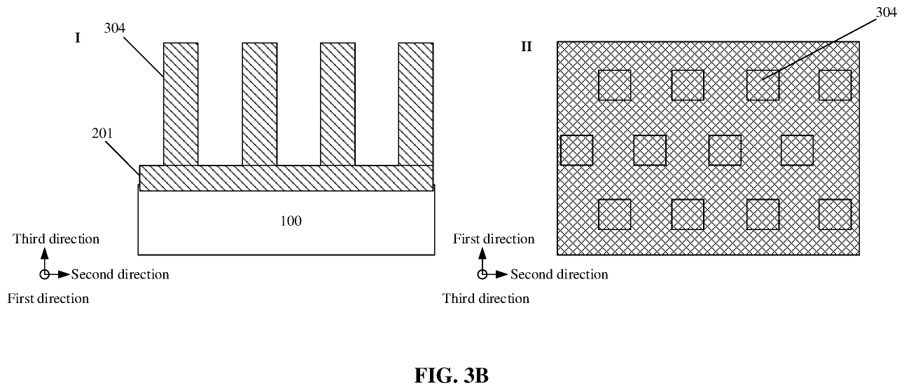

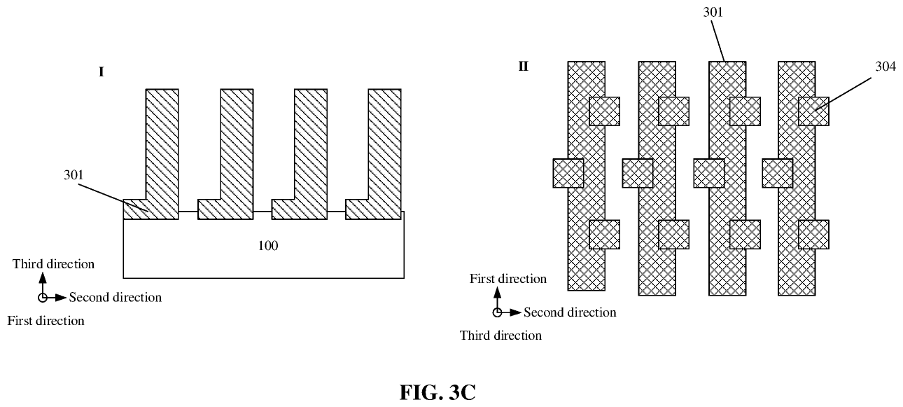

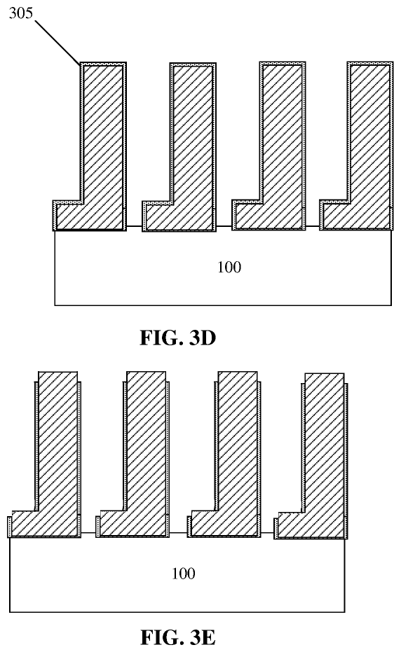

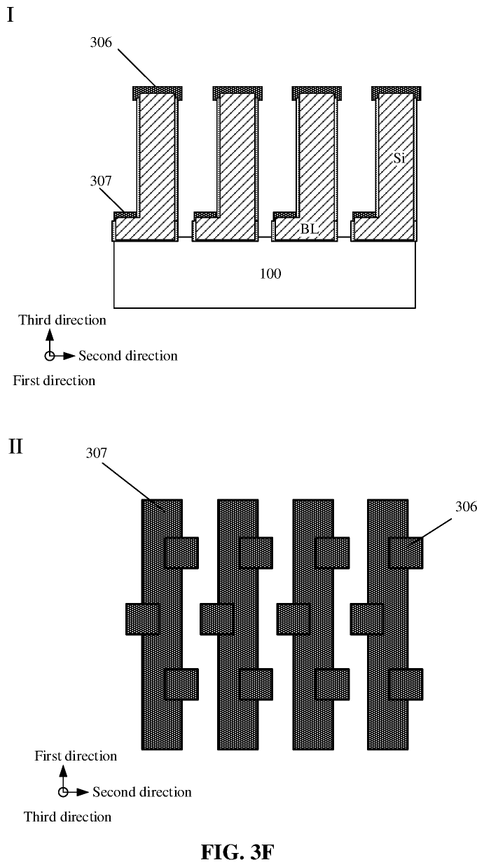

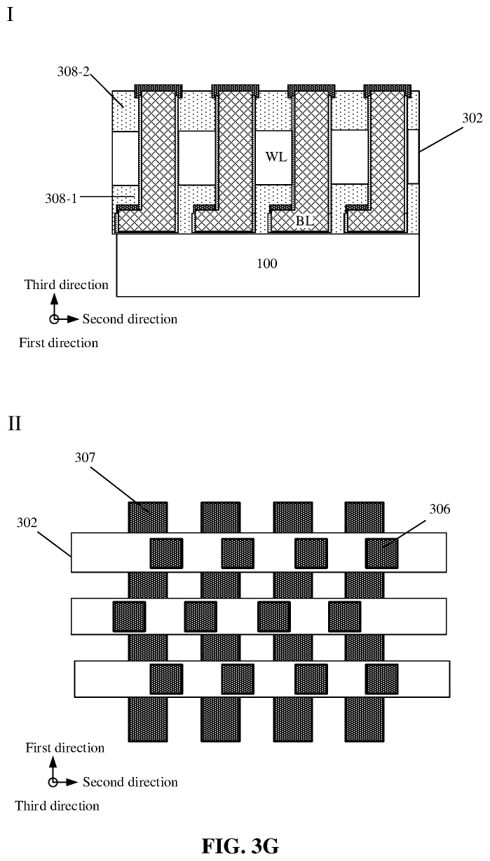

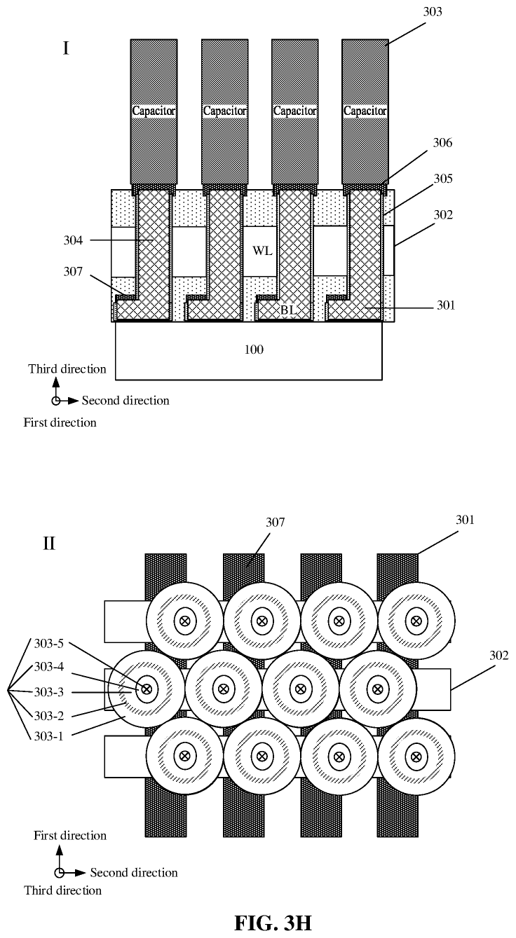

FIG. 3A to FIG. 3H are schematic cross-sectional views of device structures in a process for manufacturing of a memory provided by an embodiment of the disclosure.

First, the operation 501 is performed. With reference to FIG. 3A, the substrate 100 is provided. The substrate 100 may be, for example, a substrate of an elemental semiconductor material (for example, silicon (Si) substrate, germanium (Ge) substrate, etc.), a substrate of a composite semiconductor material (for example, silicon germanium (SiGe) substrate, etc.), a silicon on insulator (SOI) substrate, a germanium on insulator (GeOI) substrate, and the like.

Next, the operation 502 is performed. With reference to FIG. 3A to FIG. 3B, a plurality of active pillars 304 are formed, the plurality of active pillars 304 are disposed on the substrate and arranged in hexagonal array.

In practice, first, as shown in FIG. 3A, a semiconductor layer 200 is formed on the substrate 100. Next, as shown in FIG. 3B, the semiconductor layer 200 is etched to form a plurality of active pillars 304 arranged in hexagonal array. It should be noted that etching is stopped above a bottom surface of the semiconductor layer 200, leaving a certain thickness of the bottom semiconductor layer 200 being not etched and serving as a bit line pre-layer 201 for subsequent formation of the bit lines 301. Specifically, before etching to form the plurality of active pillars 304, a mask layer may be first formed above the semiconductor layer 200, and the mask layer has a plurality of windows, for example arranged in hexagonal array. Then the semiconductor layer 200 is etched with the mask layer as a mask to form the plurality of active pillars 304 arranged in hexagonal array.

In practice, the semiconductor layer 200 may be formed by in-situ doping. During forming the semiconductor layer 200, a heavy doped region, a source doped region, a channel doped region and a drain doped region are sequentially formed on the semiconductor layer 200 along a direction from bottom to top, or a heavy doped region, a drain doped region, a channel doped region and a source doped region are sequentially formed on the semiconductor layer 200 along a direction from bottom to top. The heavy doped region, the source doped region, the channel doped region and the drain doped region are used to form the bit lines 301, the source regions, the channels and the drain regions, respectively.

Next, the operation 503 is performed. With reference to FIG. 3C, a plurality of bit lines 301 extending in the first direction are formed. Bottom ends of the active pillars 304 are connected to the bit lines 301.

In practice, first, a bit line mask may be formed on the active pillars 304. The bit line pre-layer 201 that is not covered by the bit line mask 400 may be etched with the bit line mask as an etching mask, so as to form the plurality of bit lines 301 extending in the first direction below the active pillars 304.

Next, the operation 504 is performed. With reference to FIG. 3D to FIG. 3F, the connecting pads 306 are formed. Each of the connecting pads 306 is disposed at a top of each of the active pillars 304 and electrically connected with the active pillar 304.

In some embodiments, the contact layers 307 are formed at the same time when forming the connecting pads. Each of the contact layers 307 is disposed on and electrically connected with a corresponding one of the bit lines 301. The connecting pads and the contact layers are formed in the same operation, such that the process can be simplified and the cost can be saved.

In an embodiment, forming the contact layers 307 at the same time when forming the connecting pads 306 includes the following operations.

Gate insulating layers are formed on the outer sidewalls of the bit lines 301 and the active pillars 304.

The gate insulating layers at tops of the active pillars 304 and the bit lines 301 is removed.

The connecting pads 306 and the contact layer 307 are formed respectively by thermal oxidation on the tops of the active pillars 304 and the bit lines 301.

Specifically, first, as shown in FIG. 3D, gate insulating layers 305 are formed on the exposed surfaces of the active pillars 304 and the bit lines 301. Next, as shown in FIG. 3E, the gate insulating layers 305 on the upper surfaces of the active pillars 304 and the bit lines 301 are removed, so that the upper surfaces of the active pillars 304 and the bit lines 301 are exposed. Next, as shown in FIG. 3F, the connecting pads 306 and the contact layers 307 are formed on the exposed upper surfaces of the active pillars 304 and the upper surfaces of the bit lines 301, respectively. Each of the connecting pads 306 is disposed on the top of a corresponding one of the active pillars 304 and electrically connected to the active pillar 304. Each of the contact layers 307 is disposed on the upper surface of a corresponding one of the bit lines 301 and electrically connected to the bit line 301.

In practice, a material of the gate insulating layers 305 includes, but is not limited to, silicon oxide, silicon oxynitride or a High-K material, etc. The gate insulating layers 305 may be formed by thermal oxidation. In addition, the gate insulating layers 305 on the upper surfaces of the active pillars 304 may be removed by dry etching, for example, including, but not limited to, reactive ion etching (RIE), high density plasma etching (HDP), and the like.

In some embodiments, the material of the connecting pads and/or the contact layers 307 includes metal silicide, such as tungsten silicide, cobalt silicide, or the like. In practice, forming connecting pads 306 and contact layers 307 on the exposed upper surfaces of the active pillars 304 and the upper surfaces of the bit lines 301 respectively, includes the following operations. A metal material is formed on the upper surfaces of the active pillars 304 and the bit lines 301. Then heat treatment is performed, so that the metal material reacts with the materials of the active pillars 304 and the bit lines 301 to form metal silicide. Finally, the unreacted metal material is removed, so as to form the connecting pads 306 and the contact layers 307 on the upper surfaces of the active pillars 304 and the bit lines 301, respectively.

In some embodiments, the connecting pads and/or the contact layers are thermal treated by step annealing or alternating annealing. In practice, the step annealing includes, for example, first annealing at 1200° C., then annealing at 1000° C., and finally annealing at 800° C. The alternating annealing refers to an annealing manner of alternating annealing temperatures back and forth, for example, alternating annealing at 1000° C. and 900° C. back and forth. The connecting pads and/or the contact layers are thermal treated by step annealing or alternating annealing, which can make the formed connecting pads/contact layers more compatible with the active pillars/bit lines, and can alleviate the stress problem.

In the disclosure, by using a metal silicide with a high melting point as the material of connecting pads 306, the contact resistance between the capacitors and the transistors can be reduced, and meanwhile a high temperature capacitor process can be sustained. In addition, the connecting pads 306 and the contact layers 307 in the disclosure are formed in the same process operation, such that the process is saved and the cost is reduces.

In some embodiments, the contact layers 307 may also be in contact with the sidewalls of the active pillars 304. The contact layers 307 are in contact with the active pillars 304, which can further reduce the contact resistance between the bit lines 301 and the active pillars 304.

Next, the operation 505 is performed. With reference to FIG. 3G, a plurality of word lines 302 are formed. The word lines 302 extend in the second direction perpendicular to the first direction. The word lines 302 surround the outer sidewalls of the active pillars 304 and expose top ends of the active pillars 304 and the connecting pads 306. The active pillars 304 and the word lines 302 jointly constitute vertical memory transistors of the memory.

In practice, a lower filling layer 308-1 may be firstly formed by filling the gaps between the bit lines 301 and the active pillars 304 with a lower filling material, and then the lower filling material is etched to expose the channel doped region of the active pillars 304. Next, a word line material layer is formed on the lower filling layer, and the word line material layer covers the channel doped regions of the active pillars 304. Then, the word line material layer is etched along the second direction to form the plurality of word lines 302 extending along the first direction. The word lines 302 surround the channel doped regions of the active pillars 304. Finally, an upper filling layer 308-2 is formed by filling gaps between the word lines 302 and the active pillars 304 with an upper filling material. The plurality of connecting pads 306 are exposed from the surface of the upper filling layer 308-2.

Finally, as shown in FIG. 3H, the operation 506 is performed. A plurality of capacitors are formed, each of the capacitors 303 is located on and electrically connected with each of the connecting pads 306.

Sub-FIG. II in FIG. 3H is a top view of the capacitors 303. As shown in FIG. 3H, each of the capacitors 303 include an inner capacitor protective layer 303-5, a capacitor upper electrode 303-4, a capacitor dielectric layer 303-3, a capacitor lower electrode 303-2, and an outer capacitor protective layer 303-1 from inside to outside. In practice, an upper laminated structure in which a sacrificial layer and a supporting layer are alternately disposed may be firstly formed on the upper filling layer 308-2 and the connecting pads 306. Then, a plurality of through holes are formed. The through holes penetrate the upper laminated structure sequentially to expose the connecting pads 306. Next, the capacitor lower electrodes 303-2 are formed. The capacitor lower electrodes 303-2 cover the sidewalls and bottoms of the through holes, so as to form a plurality of tubular structures. The sacrificial layer is removed. The remaining supporting layer connects the outer walls of the capacitor lower electrode with the tubular structure. Then, the capacitor dielectric layer 303-3 and the capacitor upper electrode 303-4 are formed sequentially on the surface inside each of the capacitor lower electrodes 303-2. Finally, the inner capacitor protective layer 303-5 is formed, which fills the inside of the tubular structure formed by the capacitor upper electrode 303-4, and the outer capacitor protective layer 303-1 is formed, which covers the outer sidewall of the tubular structure formed by the capacitor lower electrode 303-2.

After the capacitors 303 are manufactured, a filling material may further be used to fill gaps between the capacitors and cover the tops of the capacitors 303, so as to form a supporting layer in the gaps between the capacitors and a cap layer on the tops of the capacitors 303.

The above manufacturing method is only an example of a method for manufacturing a memory provided by an embodiment of the disclosure. It should be understood that the above-mentioned embodiment is not the only definition on the method for manufacturing a memory provided by the disclosure. In some embodiments, forming a plurality of active pillars, the plurality of active pillars being disposed on the substrate and arranged in hexagonal array, and forming a plurality of bit lines, the bit lines extending along a first direction, and bottom ends of the active pillars being connected to the bit lines, may also be implemented by the following manner. A bit line material layer is formed on the substrate 100. The bit line material layer is etched along the first direction to form the plurality of bit lines 301 extending along the first direction. A filling layer fills gaps between the adjacent bit lines 301. Tops of the bit lines 301 and the filling material are planarized, so that the tops of the bit lines 301 are flush with the top of the filling material. A sacrificial layer is formed. The sacrificial layer is etched to form a plurality of through holes. A part of the bit lines 301 are exposed by the through holes. The through holes are arranged in hexagonal array. An active material is then filled in the through holes to form the active pillars 304. Herein, the active pillars may be formed by in-situ doping, so as to form a source doped region, a channel doped region and a drain doped region, or a drain doped region, a channel doped region and a source doped region from bottom to top respectively. In the embodiment, the sacrificial layer may be removed later. After removing the sacrificial layer, the operations 503 to 506 as in the above-mentioned embodiments may be implemented to achieve the manufacturing of the memory provided by the embodiment of the disclosure.

In summary, the disclosure adopts the vertical memory transistors with the vertical structure, which occupies a smaller area on the substrate and can suppress short-channel effect by adjusting the height of the active pillars. Meanwhile, the plurality of active pillars are arranged in a hexagonal array manner, which can maximize the space utilization rate and the arrangement density of the capacitors in the memory.

It should be noted that, the memory and the method for manufacturing the same provided by the embodiments of the disclosure can be applied to any integrated circuit including the structure. The technical features in the technical solutions described in each embodiment can be arbitrarily combined without conflict.

The above is only the preferred embodiments of the disclosure, and is not intended to limit the protection scope of the disclosure. Any modification, equivalent replacement and improvement made within the spirit and principles of the disclosure shall be included in the protection scope of the disclosure.

A structure of the vertical storage transistors is adopted in the disclosure, and the vertical storage transistors is disposed in a hexagonal array manner, which can allow the capacitors to realize a closest structure of hexagonal closet pack, thus obtaining a maximum gain of the capacitors. Meanwhile, the occupied area of a memory cell can be further reduced by the design of the vertical transistors compared to a structure of horizontal transistors, and a storage density can be further improved. In addition, a problem of bit line (BL)/capacitor contact (NC) coupling in a traditional structure can be solved by disposing the vertical transistors. Meanwhile, the whole structure is very regular, thus having an excellent implementability in the process and an ideal stability.

1. A memory, comprising:
a substrate;
a plurality of bit lines located on the substrate, the plurality of bit lines being parallel to each other and extending in a first direction;
a plurality of active pillars located on the bit lines, bottom ends of the active pillars being connected to the bit lines;
a plurality of word lines parallel to each other and extending in a second direction, the word lines surrounding outer sidewalls of the active pillars and exposing top ends of the active pillars, and the active pillars and the word lines jointly constituting vertical memory transistors of the memory; and
a plurality of capacitors and a plurality of connecting pads, each of the capacitors being located on each of the active pillars, and each of the connecting pads being located between the active pillar and the capacitor for electrically connecting the active pillar and the capacitor;
wherein the first direction and the second direction are perpendicular to each other, and the plurality of active pillars are arranged in hexagonal array.

2. The memory of claim 1, wherein,
in a projection on a plane perpendicular to a third direction, a center of each of the active pillars is offset from a central axis of the bit line to which the active pillar is connected, and the centers of two adjacent ones of the active pillars on a same bit line are offset in opposite directions from the central axis of the bit line, wherein the third direction is perpendicular to the first direction and the second direction, and the central axis of the bit line extends along the first direction.

3. The memory of claim 1, comprising:
a memory cell constituted by one of the vertical memory transistors and the capacitor located on the vertical memory transistor, and a cell size of the memory cell is 4F².

4. The memory of claim 2, wherein,
the plurality of bit lines are arranged in parallel and spaced apart from each other at an equal interval; a distance between two adjacent ones of the bit lines is a bit line distance, and a distance between the center of one of the active pillars and the central axis of the bit line to which the active pillar is connected is an offset distance, wherein the offset distance is ⅓ to ⅔ of the bit line distance.

5. The memory of claim 1, further comprising:
contact layers, located one-to-one on the bit lines and electrically connected with the bit lines.

6. The memory of claim 5, wherein,
each of the connecting pads comprises a first connecting pad extending perpendicular to a third direction and a second connecting pad extending in the third direction, the first connecting pad covers a top of one of the active pillars, and the second connecting pad is in contact with the first connecting pad and covers a part of the sidewall of the one of the active pillars; and/or,
each of the contact layers comprises a horizontal portion extending perpendicular to the third direction and a vertical portion extending parallel to the third direction, the horizontal portion covers a top of one of the bit lines, and the vertical portions extends along a sidewall of the one of the bit lines;
wherein the third direction is perpendicular to the first direction and the second direction.

7. The memory of claim 6, wherein,
along the third direction, a ratio of a height of the second connecting pad to a height of a portion of the active pillar above the word line is 0.5-0.75.

8. The memory of claim 6, wherein,
along the third direction, a ratio of a height of the vertical portion to a height of the bit line is 0.6-0.9.

9. The memory of claim 5, wherein,
a material of the connecting pads and a material of the contact layers are same.

10. The memory of claim 5, wherein,
the material of the connecting pads and/or the material of the contact layers comprises metal silicide.

11. The memory of claim 5, wherein,
each of the connecting pads and/or each of the contact layers comprises a multi-layer structure, and materials of respective layers of the multi-layer structure are different.

12. A method for manufacturing a memory, comprising:
provide a substrate;
forming a plurality of active pillars, the plurality of active pillars being disposed on the substrate and arranged in hexagonal array;
forming a plurality of bit lines, the bit lines being parallel to each other and extending in a first direction, and bottom ends of the active pillars being connected to the bit lines;
forming connecting pads, each of the connecting pads being disposed at a top of each of the active pillars and electrically connected with the active pillar;
forming a plurality of word lines parallel to each other and extending in a second direction perpendicular to the first direction, the word lines surrounding outer sidewalls of the active pillars, top ends of the active pillars and the connecting pads being exposed out of the word lines, and the active pillars and the word lines jointly constituting vertical memory transistors of the memory; and
forming a plurality of capacitors, each of the capacitors being disposed on and electrically connected with each of the connecting pads.

13. The method of claim 12, further comprising:
forming contact layers at the same time when forming the connecting pads, each of the contact layers being disposed on and electrically connected with each of the bit lines.

14. The method of claim 13, wherein forming contact layers at the same time when forming the connecting pads comprises:
forming gate insulating layers on outer sidewalls of the bit lines and the active pillars;
removing the gate insulating layers at tops of the active pillars and the bit lines; and
forming the connecting pads and the contact layers respectively by thermal oxidation on the tops of the active pillars and the bit lines.

15. The method of claim 12, wherein forming a plurality of word lines comprises:
forming a lower filling layer by filling gaps between the bit lines and the active pillars with a lower filling material and etching back the lower filling material to expose channel doped regions of the active pillars;
forming the plurality of word lines extending in the first direction by forming a word line material layer on the lower filling layer and etching the word line material layer along the second direction, the word lines surrounding the channel doped regions of the active pillars; and
forming an upper filling layer by filling gaps between the word lines and the active pillars with an upper filling material.

16. The method of claim 12, further comprising:
thermal treating the connecting pads by step annealing or alternating annealing after the connecting pads are formed.
